(19) United States
(12) Patent Application Publication
(10) Pub. No.: US 2017/0276703 A1
(43) Pub. Date: Sep. 28, 2017

(54) STRUCTURE OF LASER CLEANING MACHINE

(71) Applicant: GIGA SOLUTION TECHNOLOGY CO., LTD., Hsinchu (TW)

(72) Inventors: LIANG-PO CHEN, Hsinchu (TW); SHANG-WEI CHIANG, Hsinchu (TW)

(21) Appl. No.: 15/076,665

(22) Filed: Mar. 22, 2016

(51) Int. Cl. G01R 3/00; B08B 7/00

(52) U.S. Cl. CPC G01R 3/00; B08B 7/0042

(57) ABSTRACT

The structure of a laser cleaning machine contains a laser generation device for cleaning a to-be-cleaned object, a platform for supporting the to-be-cleaned object under a projection path of the laser generation device, an image capture device configured on the laser generation device, and a cleaning and control device inside the image capturing device for setting a traversal path of the laser generation device and for processing information obtained by the image capturing device. The image capturing device contains a first capturing element and a second capturing element to a side of the first capturing element. The cleaning and control device obtains the location distribution and the precise coordinate of each contactor element on the to-be-cleaned object, and then determines an optimized traversal path and instructs the laser generation device to conduct cleaning accordingly so as to achieves high-quality and highly efficient cleaning.

### BACKGROUND OF THE INVENTION

(a) Technical Field of the Invention

The present invention is generally related to probe cards, and more particular to a structure of a laser cleaning machine of superior cleaning effect and efficiency.

(b) Description of the Prior Art

In order to test a wafer, it is required to apply voltages or signals to the electrodes of the various integrated circuits on the wafer so as to drive the various integrated circuits. Therefore, a probe card having a large number of contactors for contacting the electrodes of the integrated circuits has to be prepared and utilized.

In addition, to appropriately test the electrical characteristics of the integrated circuits, the insulating aluminum oxidation layers on the electrode surfaces have to be removed so that the contactors can reliably contact the electrodes with specific pressure. However, as such, some aluminum or impurity would be attached to the contactors' tips as bumps and these bumps may damage the electrodes when the contactors touch the electrodes.

Maintaining cleaned contactors is therefore very important. Depending on the brands, types, and usages of various probe cards, their contactors are arranged differently and their cleaning has to be very careful so as not to damage the contactors. Additionally, some contactors may be missed during the cleaning process and more effort has to be spent to remedy this problem.

In summary, the probe card cleaning involves the following issues.

Firstly, the cleaning is inconvenient or the cleaning effect is less satisfactory. In the worst case, some contactors may suffer deteriorated function or shape deformation.

Secondly, the cleaning process may miss some contactors, causing inferior cleaning efficiency.

### SUMMARY OF THE INVENTION

The present invention therefore teaches a structure of a laser cleaning machine to achieve superior cleaning effect and efficiency.

A major objective of the present invention is to use laser to enhance cleaning quality and, together with image capture and control, to optimize a cleaning path and positioning precision, so as to achieve speedy cleaning.

To achieve the above objective, the structure of a laser cleaning machine contains a laser generation device for cleaning a to-be-cleaned object, a platform for supporting the to-be-cleaned object under a projection path of the laser generation device, an image capture device configured on the laser generation device containing a first capturing element and a second capturing element to a side of the first capturing element, and a cleaning and control device inside the image capturing device for setting a traversal path of the laser generation device and for processing information obtained by the image capturing device. The structure of a laser cleaning machine is operated as follows. The to-be-cleaned object is placed on the platform. The first and second capturing elements then obtain location information for the to-be-cleaned object. Subsequently, the cleaning and control device obtains the location distribution and the precise coordinate of each contactor element. The cleaning and control device then determines an optimized traversal path, and instructs the laser generation device to conduct cleaning accordingly. As described above, the present invention quickly and conveniently determines the location information of the to-be-cleaned object and, together with the optimized path and laser cleaning, achieves high-quality and highly efficient cleaning.

The prior art's problems such as inconvenience, inferior cleaning effect, missing contactor elements, and low efficiency are all resolved by the present invention.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective diagram showing a structure of a laser cleaning machine according to an embodiment of the present invention.

FIG. 2 is a functional block diagram showing the structure of a laser cleaning machine of FIG. 1.

FIG. 3 is a perspective schematic diagram showing the operation of the structure of a laser cleaning machine of FIG. 1.

FIG. 4 is another perspective schematic diagram showing the operation of the structure of a laser cleaning machine of FIG. 1.

FIG. 5 is yet another perspective schematic diagram showing the operation of the structure of a laser cleaning machine of FIG. 1.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

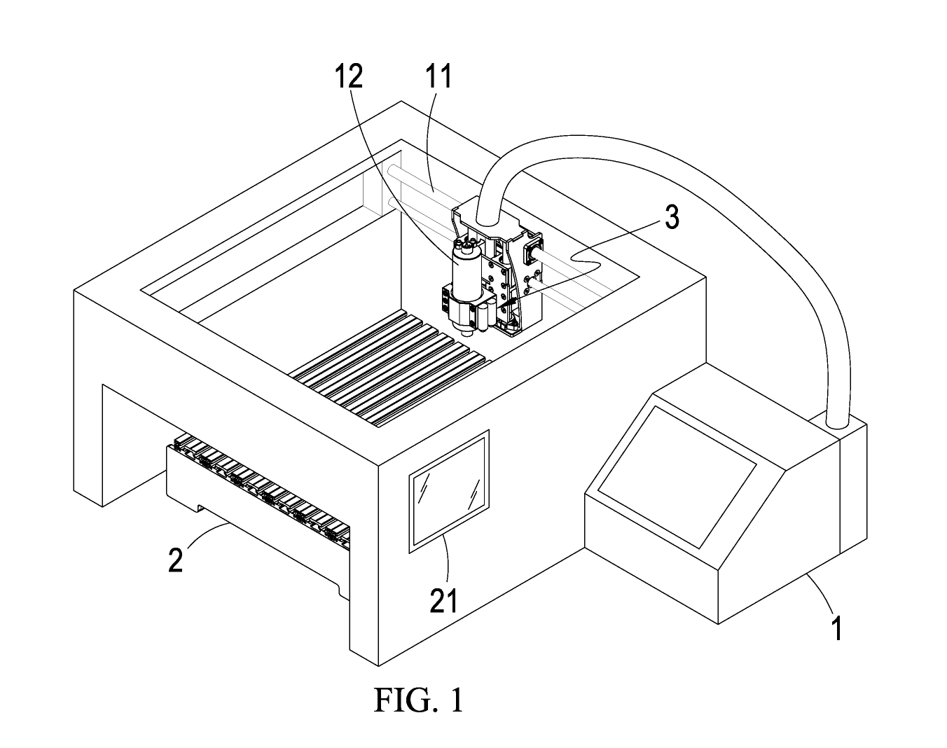

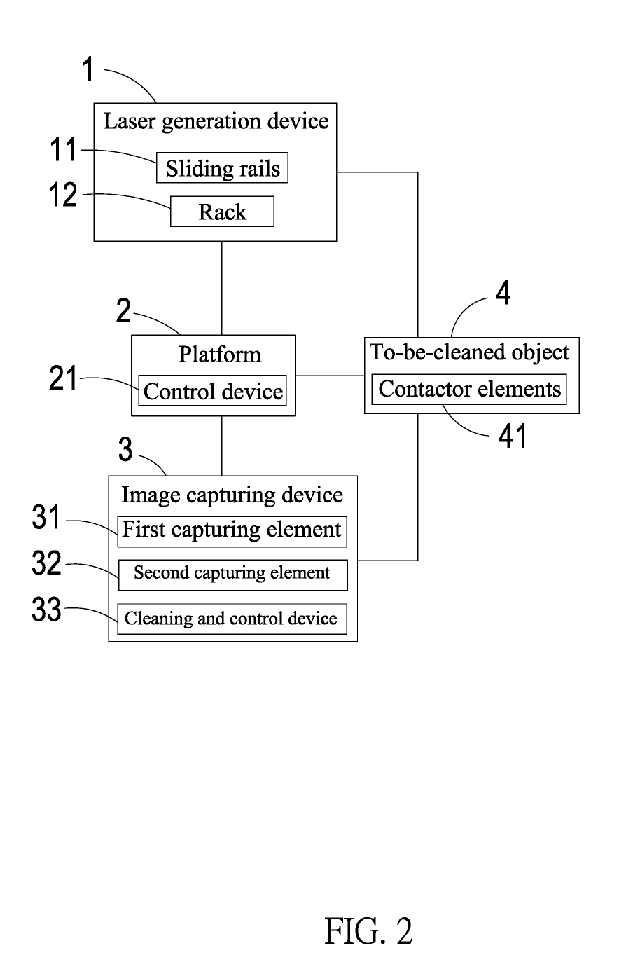

As shown in FIGS. 1 and 2, a laser cleaning machine according to an embodiment of the present invention is for cleaning a to-be-cleaned object 4. In the present embodiment, the to-be-cleaned object 4 is a probe card having an array of contactor elements 41. The probe card can be of various types such as the cantilever probe card, the vertical probe card, the membrane probe card, the pogo probe card, the micro spring probe card, or the MEMS (Micro Electro Mechanical System) probe card.

The laser cleaning machine contains a laser generation device 1. The laser generation device 1 contains a pair of linear sliding rails 11, and a rack 12 moveably configured on the sliding rails 11. The laser generation device 1 is charged by an AC voltage between 650V and 1,000V, has a radiation wave length between 532 nm (nano meter) and 1,064 nm, and a radiated pulse energy between 400 mJ (micro Joule) and 1,200 mJ.

The laser cleaning machine further contains a platform 2 for supporting the to-be-cleaned object 4 under a projection path of the laser generation device 1. There is a control device 21 for controlling the laser generation device 1 and an image capture device 3 described below.

The image capture device 3 is configured on the rack 12, and contains a first capturing element 31 and a second capturing element 32 to a side of the first capturing element 31. The first and second capturing elements 31 and 32 contain low- and high-power lenses, respectively. The first capturing element 31 obtains the location distribution information of the contactor elements 41 while the second capturing element 32 obtains the precise coordinate information of the contactor elements 41.

The image capturing device 3 further contains a cleaning and control device 33 inside for setting a traversal path of the laser generation device 1 and for processing the information obtained by the image capturing device 3.

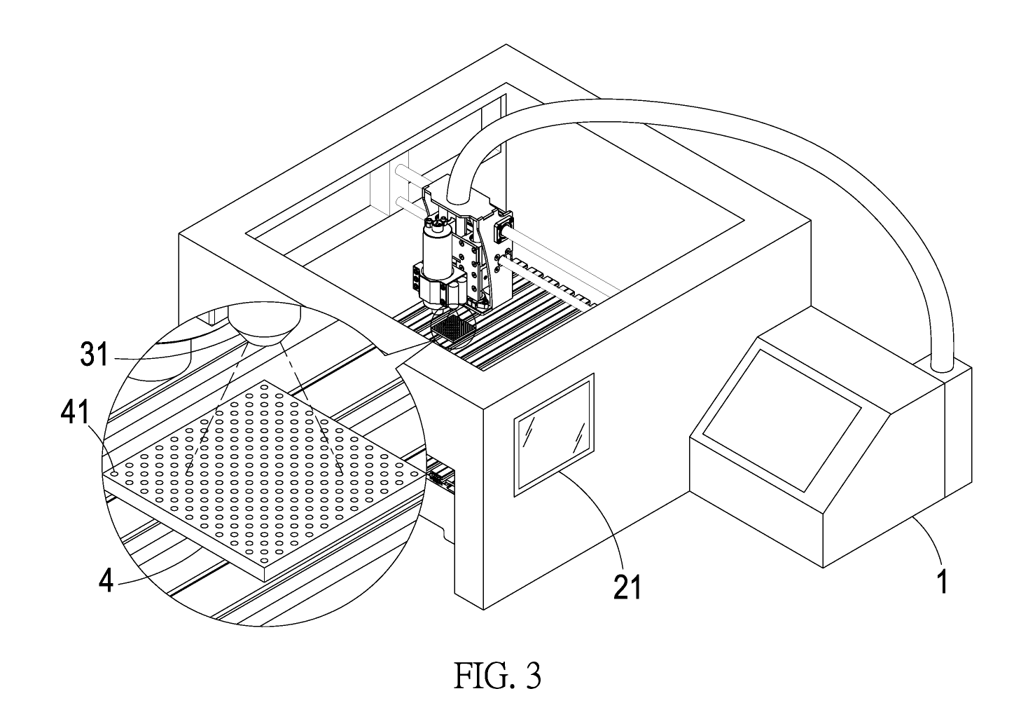

As shown in FIGS. 3 to 5, the image capturing device 3 contains a low-power first capturing 31 for obtaining the location distribution information of the contactor elements 41 and a high-power second capturing element 32 for obtaining the precise coordinate information of the contactor elements 41. Then, with the cleaning and control device 33′s calculation and the laser's cleaning effect, highly efficient and high-quality cleaning is thereby achieved.

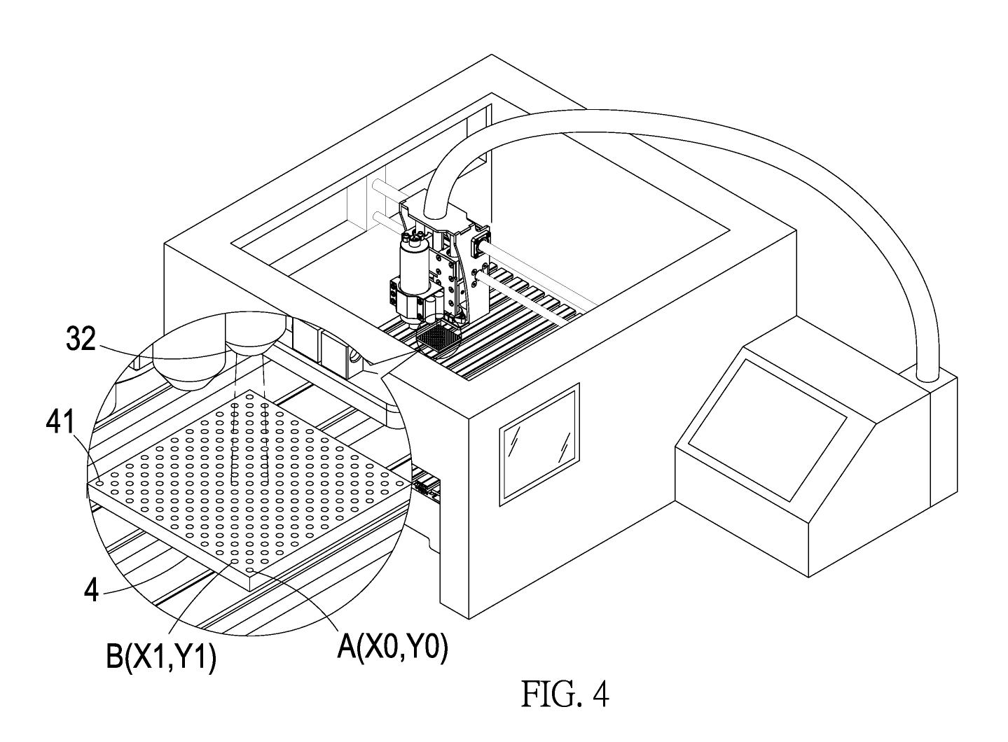

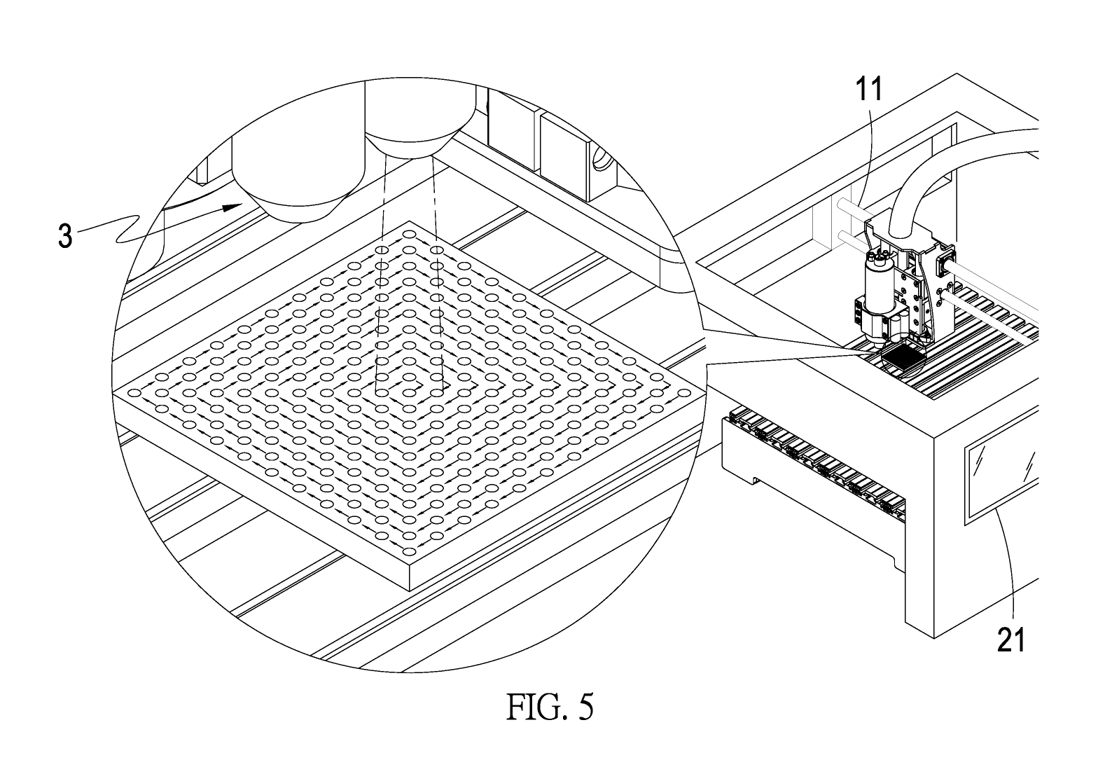

The structure of a laser cleaning machine is operated as follows. The to-be-cleaned object 4 is placed on the platform 2 first. The first capturing element 31 then obtains a rough location for each contactor element 41, and the second capturing element 32 obtains a precise coordinate for each contactor element 41. Subsequently, the first capturing element 31 scan the location distribution of the contactor elements 41 as shown in FIG. 3, and the second capturing element 32 moves from a first contactor element 41 to a second contactor element 41. By the displacement of the image capturing device 3, the precise coordinate of the second contactor element 41 can be determined. Then the precise coordinates of all contactor elements 41 are inferred similarly. As shown in FIG. 4, the B point's coordinate (X0, Y0) can be inferred form the A point's coordinate (X1, Y1). The cleaning and control device 33 then determines a better and more time-saving traversal path, and issues related commands to the laser generation device 1 to move the sliding rails 11 and the rack 12 accordingly. The traversal path, depending on the distribution of the contactor elements 41, can be of S-like shapes, diamond-like shapes, or square shapes (as shown in FIG. 5). The above operation can be easily accomplished by the control device 21.

Furthermore, conventional laser cleaning device usually cannot adjust the energy according to the to-be-cleaned object 4 (i.e., probe card) and therefore the strength may not be sufficient to achieve thorough cleaning. A conventional laser cleaning device may also repeatedly apply laser to the to-be-cleaned object 4 so as to dissolve the impurity on the to-be-cleaned object 4, thereby damaging the to-be-cleaned object 4. The present invention therefore calculates an appropriate range of pulse energy for various probe cards by applying AC charging voltage between 650V and 1,000V, and radiation wave length between 532 nm and 1,064 nm, thereby achieving a radiated pulse energy between 400 mJ and 1,200 mJ. For example, an appropriate energy for a membrane probe card is 800 mJ.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

1. A structure of a laser cleaning machine comprising:
a laser generation device for cleaning a to-be-cleaned object;
a platform for supporting the to-be-cleaned object under a projection path of the laser generation device;
an image capturing device configured on the laser generation device comprising a first capturing element and a second capturing element to a side of the first capturing element, wherein the first capturing element comprises a first lens having a first power for obtaining location distribution information of the contactor elements; and the second capturing element comprises a second lens having a second power for obtaining precise coordinate information of the contactor elements, the first power being lower than the second power; and
a cleaning and control device inside the image capturing device that is operable for processing information obtained by the image capturing device in order to determine a traversal path for the laser generation device according to the processed information,
wherein the laser generation device has an AC charging voltage between 650V and 1,000V;
wherein a wave length produced by the laser generation device is between 532 nm and 1,064 nm; and
wherein a pulse energy produced by the laser generation device is between 400 mJ and 1,200 mJ.

2. The structure of a laser cleaning machine according to claim 1, wherein there are a plurality of contactor elements configured at intervals on the to-be-cleaned object.

3-4. (canceled)

5. The structure of a laser cleaning machine according to claim 1, further comprising a control device on the platform for controlling the laser generation device and the image capture device.

6. The structure of a laser cleaning machine according to claim 1, wherein the laser generation device comprises a pair of linear sliding rails and a rack moveably configured on the sliding rails.

7-9. (canceled)

10. The structure of a laser cleaning machine according to claim 1, wherein the to-be-cleaned object is one of a cantilever probe card, a vertical probe card, a membrane probe card, a pogo probe card, a micro spring probe card, and a Micro Electro Mechanical System (MEMS) probe card.
